(19) United States
(12) Patent Application Publication
(10) Pub. No.: US 2018/0215660 A1
(43) Pub. Date: Aug. 2, 2018

(54) Method for the Fabrication of a Reduced Reflectance Metal Mesh

(71) Applicant: Zhihong Liu, San Marcos, TX (US)

(72) Inventor: Zhihong Liu, San Marcos, TX (US)

(73) Assignee: 2M Technology, LLC, Austin, TX (US)

(21) Appl. No.: 15/417,417

(22) Filed: Jan. 27, 2017

(51) Int. Cl. C03C 17/36; C03B 19/02; C03C 17/40; C03C 15/00; H01J 37/305

(52) U.S. Cl. CPC C03C 17/3639; C03B 19/02; C03C 17/3644; C03C 17/3655; C03C 17/3657; H01J 2237/3151; C03C 15/00; H01J 37/3053; C03C 2217/261; C03C 2218/151; C03C 2218/154; C03C 17/40

(57) ABSTRACT

Methods for fabricating a reduced reflectance metal mesh are disclosed, including depositing a brittle layer onto a substrate; forming micro-cracks in the brittle layer; depositing a reduced reflectance layer onto the micro-cracked brittle layer; depositing a reduced reflectance layer onto the micro-cracked brittle layer; depositing a conductive material onto the reduced reflectance layer; and performing a lift-off of the brittle layer from the substrate, resulting in the reduced reflectance metal mesh atop the substrate. Other embodiments are described and claimed.

### I. BACKGROUND

The invention relates generally to the field of metal mesh electrodes. More particularly, the invention relates to a method for the fabrication of metal mesh electrodes with reduced reflectance.

### II. SUMMARY

In one respect, disclosed is a method for fabricating a reduced reflectance metal mesh, the method comprising: depositing a brittle layer onto a substrate; forming micro-cracks in the brittle layer; depositing a reduced reflectance layer onto the micro-cracked brittle layer; depositing a conductive material having a higher reflectance than the reduced reflectance layer onto the reduced reflectance layer; and performing a lift-off of the brittle layer from the substrate, resulting in the reduced reflectance metal mesh atop the substrate.

In another respect, disclosed is a method for fabricating a reduced reflectance metal mesh, the method comprising: depositing a reduced reflectance layer onto a substrate; depositing a brittle layer onto the reduced reflectance layer; forming micro-cracks in the brittle layer; depositing a conductive material having a higher reflectance than the reduced reflectance layer onto the micro-cracked brittle layer; performing a lift-off of the brittle layer from the reduced reflectance layer, resulting in a metal mesh structure atop the reduced reflectance layer; and dissolving and/or reactive ion etching the portion of the reduced reflectance layer not covered by the conductive material, resulting in the reduced reflectance metal mesh atop the substrate.

Numerous additional embodiments are also possible.

### III. BRIEF DESCRIPTION OF THE DRAWINGS

Other objects and advantages of the invention may become apparent upon reading the detailed description and upon reference to the accompanying drawings.

FIGS. 1A, 1B, 1C, 1D, and 1E are cross-sectional illustrations of the steps in fabricating a metal mesh with reduced reflectance, in accordance with some embodiments.

FIGS. 2A, 2B, 2C, 2D, 2E, and 2F are cross-sectional illustrations of the steps in fabricating a metal mesh with reduced reflectance, in accordance with some embodiments.

FIG. 3 is a block diagram illustrating a method for forming metal mesh electrodes with reduced reflectance, in accordance with some embodiments.

FIG. 4 is a block diagram illustrating a method for forming metal mesh electrodes with reduced reflectance, in accordance with some embodiments.

While the invention is subject to various modifications and alternative forms, specific embodiments thereof are shown by way of example in the drawings and the accompanying detailed description. It should be understood, however, that the drawings and detailed description are not intended to limit the invention to the particular embodiments. This disclosure is instead intended to cover all modifications, equivalents, and alternatives falling within the scope of the present invention as defined by the appended claims.

### IV. DETAILED DESCRIPTION

One or more embodiments of the invention are described below. It should be noted that these and any other embodiments are exemplary and are intended to be illustrative of the invention rather than limiting. While the invention is widely applicable to different types of systems, it is impossible to include all of the possible embodiments and contexts of the invention in this disclosure. Upon reading this disclosure, many alternative embodiments of the present invention will be apparent to persons of ordinary skill in the art.

Transparent conducting electrodes (TCEs), which have high optical transparency and high electrical conductivity, are widely used in many optoelectronic devices, such as organic/inorganic light emitting diodes, solar cells, liquid crystal displays and touch panels and also in other applications such as in transparent heaters and in electromagnetic (EM) shielding. Historically, the use of indium tin oxide (ITO) has dominated the TCE industry. However, due to ITO's brittleness, high cost, high optical diffraction index, limited conductivity, and limited transparency, alternatives to the use of ITO are desirable. Alternatives such as metal mesh, metal nanowire, graphene, and carbon nanotube have attracted attention as alternatives to ITO. Of these alternatives, metal mesh and metal nanowire networks are especially attractive due to their excellent combination of high conductivity and high transparency. In the case of metal mesh electrodes, the use of highly reflective metal, such as silver and copper, leads to visibility problems. To minimize these visibility problems, a metal mesh with reduced reflectance is necessary. A method for the fabrication of metal mesh electrodes with reduced reflectance is disclosed herein.

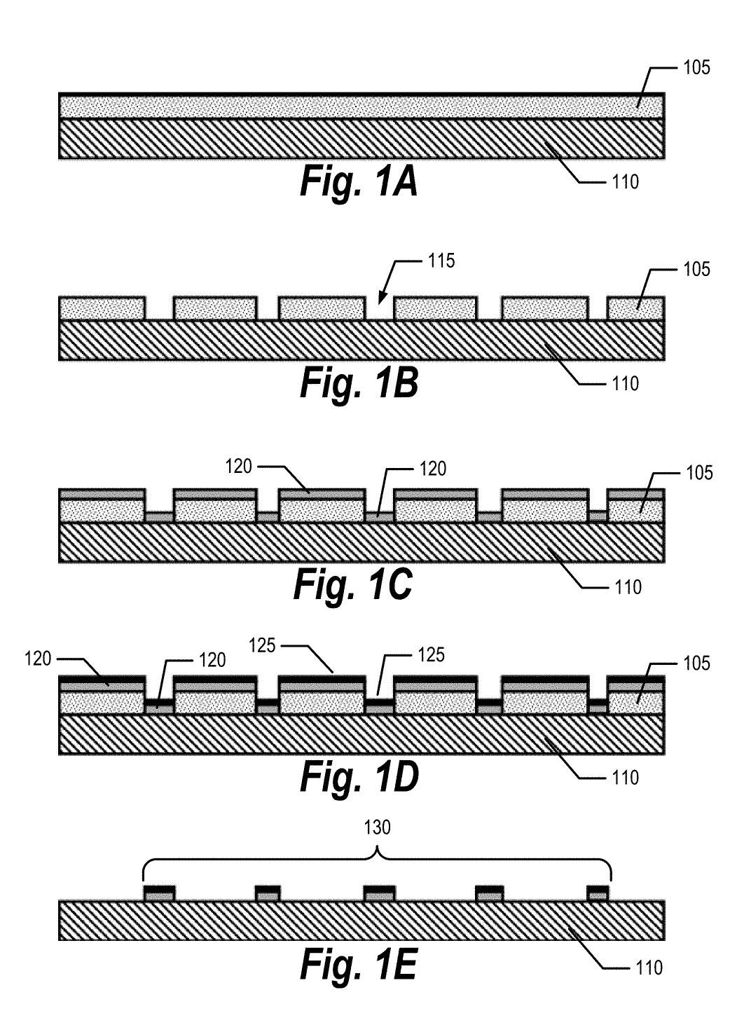

FIGS. 1A, 1B, 1C, 1D, and 1E are cross-sectional illustrations of the steps in fabricating a metal mesh with reduced reflectance, in accordance with some embodiments.

In some embodiments, a brittle layer 105 is deposited onto a substrate 110 as illustrated in FIG. 1A. The brittle layer 105 may comprise spin-on-glass, liquid glass, ceramic, salt, carbon, and/or PMMA. The substrate 110 may comprise any transparent and flexible film, such as polyethylene terephthalate (PET), polyimide (PI), cellulose, polyester, polyethylene, flexible glass, and/or other similar materials. In one embodiment, a brittle layer of spin-on-glass, such as P-102F spin-on-glass from Filmtronics, was coated onto a substrate of cleaned PET film at a thickness between about 75-150 μm by a micro-gravure roll to roll coater from MIRWEC Film, Inc. The brittle layer and substrate were subsequently dried in air at room temperature for 2 hours. Next, micro-cracks 115 are formed in the brittle layer 105. Various methods, such as mechanical bending, stretching, squeezing, pressing, thermal shock, quenching, and adding nanoparticles, such as silver, copper, gold, iron, nickel, cobalt, platinum, palladium, titanium, aluminum, chromium, and/or molybdenum, in the brittle layer 105, may be used to form micro-cracks 115 in the brittle layer 105 as shown in FIG. 1B. In one embodiment, the dried brittle layer and substrate were thermally shocked and annealed by baking on a hot plate at 110° C. for 3 minutes to form micro-cracks in the brittle layer. In other embodiments, the annealing may comprise a temperature ranging from about 40° C. to about 180° C. and a time ranging from about 10 seconds to about 1 hour. After the micro-cracks 115 have been formed, a reduced reflectance layer 120, comprising dyes, metals, alloys, or semiconductors, having a material selected from the group consisting of nickel-phosphorous, nickel, iron, chromium, nickel oxide, iron oxide, copper oxide, silicon, germanium, graphite, graphene, carbon nanotube, or a combination thereof, is deposited onto the micro-cracked brittle layer, resulting in a low reflectance layer on top of the brittle layer and on top of the substrate within the micro-cracks, as shown in FIG. 1C. In one embodiment, a 40 nm thick nickel-phosphorous (Ni—P) alloy reduced reflectance layer was deposited by sputtering onto the micro-cracked brittle layer. Then a layer of conductive material 125, comprising metals, alloys, and/or doped semiconductor with a higher reflectance than the reduced reflectance layer, is deposited onto the reduced reflectance layer 120 as shown in FIG. 1D. In one embodiment, a 120 nm thick silver layer was deposited onto the reduced reflectance Ni—P alloy layer by e-beam evaporation or sputtering. Next, the brittle layer is lifted-off from the substrate resulting in a structure of reduced reflectance metal mesh 130 atop the substrate 110 as illustrated in the FIG. 1E.

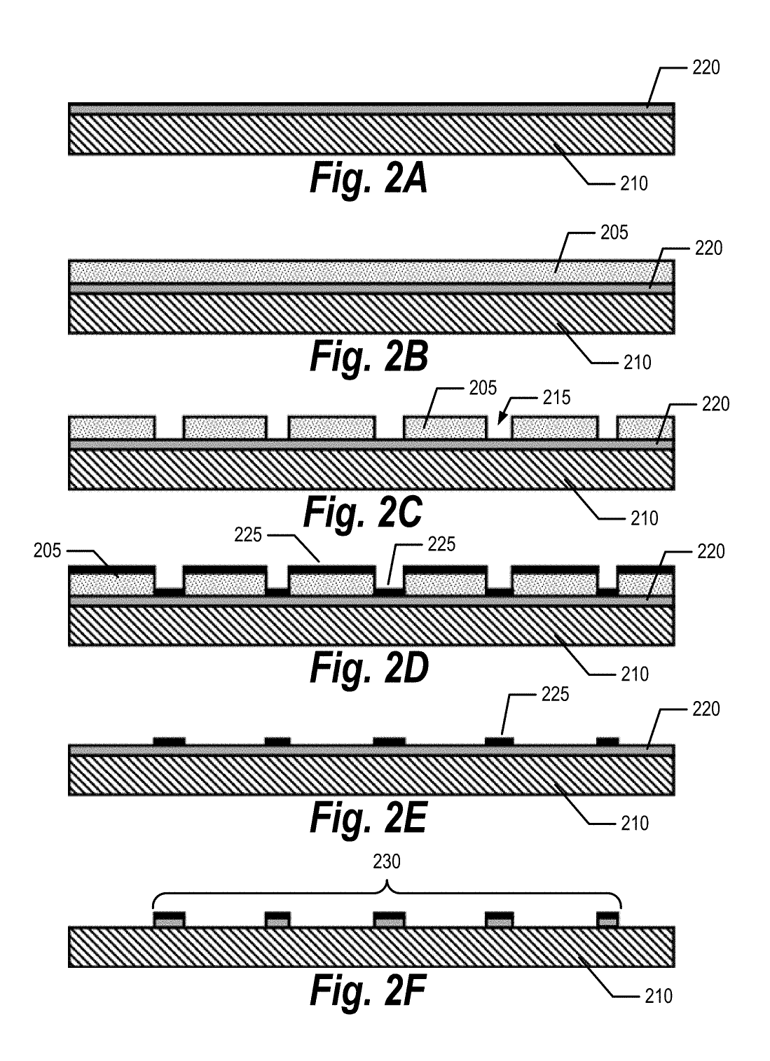

FIGS. 2A, 2B, 2C, 2D, 2E, and 2F are cross-sectional illustrations of the steps in fabricating a metal mesh with reduced reflectance, in accordance with some embodiments.

In some embodiments, a reduced reflectance layer 220 is deposited onto a substrate 210, followed by the deposition of a brittle layer 205 onto the reduced reflectance layer 220 as illustrated in FIG. 2A and FIG. 2B. The reduced reflectance layer 220 may be, but not limited to dyes, metals, alloys, or semiconductors, having a material selected from the group consisting of nickel-phosphorous, nickel, iron, chromium, nickel oxide, iron oxide, copper oxide, silicon, germanium, graphite, graphene, carbon nanotube, or a combination thereof. The thickness of the reduced reflectance layer 220 ranges from about 10 nm to about 1000 nm. The brittle layer 205 may comprise spin-on-glass, liquid glass, ceramic, salt, carbon, and/or PMMA. The substrate 210 may comprise any transparent and flexible film, such as PET, PI, cellulose, polyester, polyethylene, flexible glass, and/or other similar materials. In one embodiment, the substrate comprises a PET film coated with a reflectance layer comprising a black dye layer such as Rit DyeMore-Graphite followed by a brittle layer comprising a spin-on-glass such as P-102F from Filmtronics. The substrate, the reduced reflectance layer, and the brittle layer, were subsequently dried in air at room temperature for 2 hours. Next, micro-cracks 215 are formed in the brittle layer 205. Various methods, such as mechanical bending, stretching, squeezing, pressing, thermal shock, quenching, and adding nanoparticles, such as silver, copper, gold, iron, nickel, cobalt, platinum, palladium, titanium, aluminum, chromium, and/or molybdenum, in the brittle layer 205, may be used to form micro-cracks 215 in the brittle layer 205 as shown in FIG. 2C. In one embodiment, the dried substrate, reduced reflectance layer, and brittle layer were thermally shocked and annealed by baking on a hot plate at 110° C. for 3 minutes to form micro-cracks in the brittle layer. In other embodiments, the annealing may comprise a temperature ranging from about 40° C. to about 180° C. and a time ranging from about 10 seconds to about 1 hour. Then a layer of conductive material 225, comprising metals, alloys, and/or doped semiconductor with a higher reflectance than the reduced reflectance layer, is deposited onto the micro-cracked brittle layer as shown in FIG. 2D. Within the micro-cracks, the conductive material is deposited directly on the reduced reflectance layer 220. In one embodiment, a 160 nm thick silver layer was deposited onto the micro-cracked brittle layer, on top of the brittle layer and on top of the reduced reflectance layer within the micro-cracks, by e-beam evaporation or sputtering. Next, the brittle layer is lifted-off from the reduced reflectance layer resulting in a metal mesh structure on the reduced reflectance layer as illustrated in FIG. 2E. Lastly, the portion of the reduced reflectance layer not covered by the conductive material is dissolved using solvent and/or chemicals and/or etched by reactive-ion etching (ME) to yield a structure of reduced reflectance metal mesh 230 atop the substrate 210 as shown in FIG. 2F. In one embodiment, the portion of the black dye layer of Rit DyeMore-Graphite not covered by the conductive material was etched by Oxygen plasma etching resulting in a structure of low reflectance silver metal mesh atop the substrate.

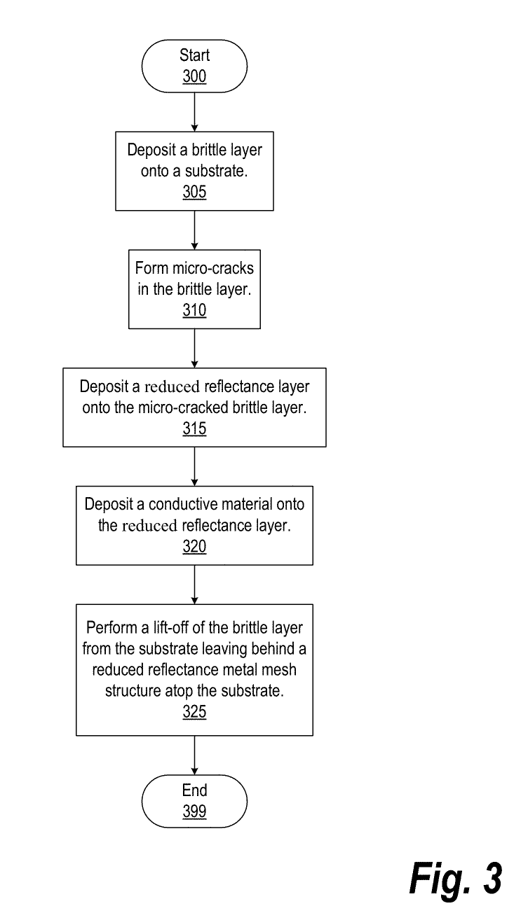

FIG. 3 is a block diagram illustrating a method for forming metal mesh electrodes with reduced reflectance, in accordance with some embodiments.

Processing begins at 300 whereupon, at block 305, a brittle layer is deposited onto a substrate. In some embodiments, the brittle layer may comprise spin-on-glass, liquid glass, ceramic, salt, carbon, and/or PMMA and the substrate may comprise any transparent and flexible film, such as PET, PI, cellulose, polyester, polyethylene, flexible glass, and/or other similar materials. At block 310, micro-cracks are formed in the brittle layer. A one dimensional and/or two-dimensional micro-crack network may be formed by mechanical bending, stretching, squeezing, pressing, thermal shock, and/or quenching. After the micro-cracks have been formed, at block 315, a reduced reflectance layer, comprising dyes, metals, alloys, or semiconductors, having a material selected from the group consisting of nickel-phosphorous, nickel, iron, chromium, nickel oxide, iron oxide, copper oxide, silicon, germanium, graphite, graphene, carbon nanotube, or a combination thereof, is deposited onto the micro-cracked brittle layer, resulting in a reduced reflectance layer on top of the brittle layer and on top of the substrate within the micro-cracks. Next, at block 320, a conductive material with a higher reflectance than the reduced reflectance layer is deposited onto the reduced reflectance layer. The conductive material may comprise metals, alloys, and/or doped semiconductor. At block 325, the brittle layer is lifted-off from the substrate resulting in a reduced reflectance metal mesh structure atop the substrate. Processing subsequently ends at 399.

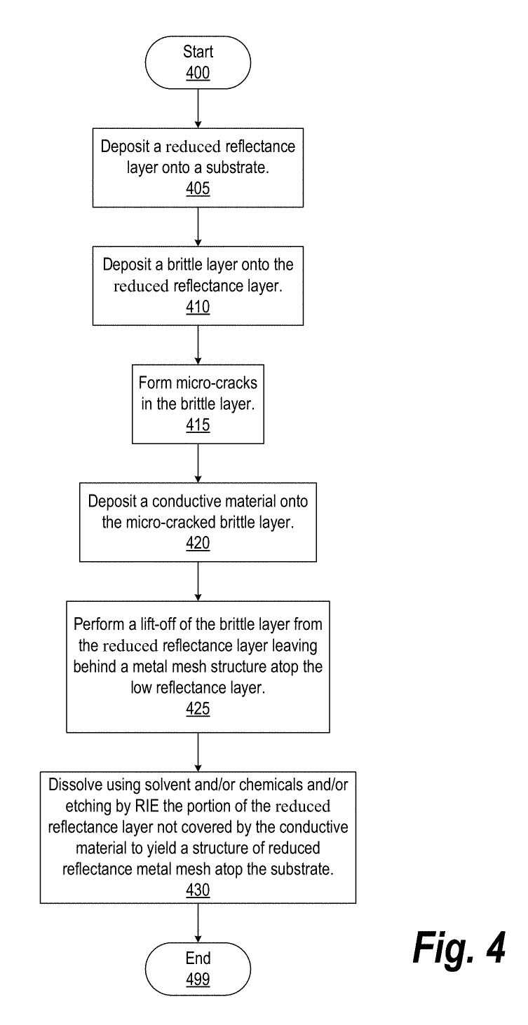

FIG. 4 is a block diagram illustrating a method for forming metal mesh electrodes with reduced reflectance, in accordance with some embodiments.

Processing begins at 400 whereupon, at block 405, a reduced reflectance layer is deposited onto a substrate. In some embodiments, the reduced reflectance layer may comprise dyes, metals, alloys, or semiconductors, having a material selected from the group consisting of nickel-phosphorous, nickel, iron, chromium, nickel oxide, iron oxide, copper oxide, silicon, germanium, graphite, graphene, carbon nanotube, or a combination thereof, and the substrate may comprise any transparent and flexible film, such as PET, PI, cellulose, polyester, polyethylene, flexible glass, and/or other similar materials. At block 410, a brittle layer is deposited onto the reduced reflectance layer. In some embodiments, the brittle layer may comprise spin-on-glass, liquid glass, ceramic, salt, carbon, and/or PMMA. At block 415, micro-cracks are formed in the brittle layer. A one-dimensional and/or two-dimensional micro-crack network may be formed by mechanical bending, stretching, squeezing, pressing, thermal shock, and/or quenching. After the micro-cracks have been formed, at block 420, a conductive material with a higher reflectance than the reduced reflectance layer is deposited onto the micro-cracked brittle layer. Within the micro-cracks, the conductive material is deposited directly on the reduced reflectance layer. The conductive material may comprise metals, alloys, and/or doped semiconductor. At block 425, the brittle layer is lifted-off from the reduced reflectance layer resulting in a metal mesh structure atop the reduced reflectance layer. At block 430, the portion of the reduced reflectance layer not covered by the conductive material is dissolved using solvent and/or chemicals and/or etched by RIE to yield a structure of reduced reflectance metal mesh atop the substrate. Processing subsequently ends at 499.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

The benefits and advantages that may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

While the present invention has been described with reference to particular embodiments, it should be understood that the embodiments are illustrative and that the scope of the invention is not limited to these embodiments. Many variations, modifications, additions and improvements to the embodiments described above are possible. It is contemplated that these variations, modifications, additions, and improvements fall within the scope of the invention as detailed within the following claims.

1. A method for fabricating a reduced reflectance metal mesh, the method comprising:
depositing a brittle layer onto a substrate;
forming micro-cracks in the brittle layer;
depositing a reduced reflectance layer onto the micro-cracked brittle layer;
depositing a conductive material having a higher reflectance than the reduced reflectance layer onto the reduced reflectance layer; and
performing a lift-off of the brittle layer from the substrate, resulting in the reduced reflectance metal mesh atop the substrate.

2. The method of claim 1, wherein forming micro-cracks in the brittle layer comprises:
mechanical bending, stretching, squeezing, pressing, thermal shock, quenching, and/or annealing the substrate and the brittle layer;
etching the brittle layer; and/or
adding nanoparticles in the brittle layer.

3. The method of claim 2, wherein the annealing comprises a temperature ranging from about 40° C. to about 180° C.

4. The method of claim 2, wherein the annealing comprises a time ranging from about 10 seconds to about 1 hour.

5. The method of claim 1, wherein the substrate comprises a transparent and flexible film having a material selected from the group consisting of polyethylene terephthalate, polyimide, cellulose, polyester, polyethylene, flexible glass, or a combination or lamination thereof.

6. The method of claim 1, wherein the brittle layer comprises spin-on-glass, liquid glass, ceramic, salt, carbon, and/or PMMA.

7. The method of claim 1, wherein the reduced reflectance layer comprises a dye, metal, alloy, and/or semiconductor having a material selected from the group consisting of nickel-phosphorous, nickel, iron, chromium, nickel oxide, iron oxide, copper oxide, silicon, germanium, graphite, graphene, carbon nanotube, or a combination thereof.

8. The method of claim 1, wherein the conductive material comprises a metal, alloy, and/or doped semiconductor having a material selected from the group consisting of silver, copper, gold, iron, nickel, cobalt, platinum, palladium, titanium, aluminum, chromium, molybdenum, or a combination thereof.

9. The method of claim 2, wherein the nanoparticles comprise silver, copper, gold, iron, nickel, cobalt, platinum, palladium, titanium, aluminum, chromium, and/or molybdenum.

10. A method for fabricating a reduced reflectance metal mesh, the method comprising:
depositing a reduced reflectance layer onto a substrate;
depositing a brittle layer onto the reduced reflectance layer;
forming micro-cracks in the brittle layer;
depositing a conductive material having a higher reflectance than the reduced reflectance layer onto the micro-cracked brittle layer;
performing a lift-off of the brittle layer from the reduced reflectance layer, resulting in a metal mesh structure atop the reduced reflectance layer; and
dissolving and/or reactive ion etching the portion of the reduced reflectance layer not covered by the conductive material, resulting in the reduced reflectance metal mesh atop the substrate.

11. The method of claim 10, wherein forming micro-cracks in the brittle layer comprises:
mechanical bending, stretching, squeezing, pressing, thermal shock, quenching, and/or annealing the substrate, the reduced reflectance layer, and the brittle layer;
etching the brittle layer; and/or
adding nanoparticles in the brittle layer.

12. The method of claim 11, wherein the annealing comprises a temperature ranging from about 40° C. to about 180° C.

13. The method of claim 11, wherein the annealing comprises a time ranging from about 10 seconds to about 1 hour.

14. The method of claim 10, wherein the substrate comprises a transparent and flexible film having a material selected from the group consisting of polyethylene terephthalate, polyimide, cellulose, polyester, polyethylene, flexible glass, or a combination or lamination thereof.

15. The method of claim 10, wherein the brittle layer comprises spin-on-glass, liquid glass, ceramic, salt, carbon, and/or PMMA.

16. The method of claim 10, wherein the reduced reflectance layer comprises a dye, metal, alloy, and or semiconductor having a material selected from the group consisting of nickel-phosphorous, nickel, iron, chromium, nickel oxide, iron oxide, copper oxide, silicon, germanium, graphite, graphene, carbon nanotube, or a combination thereof.

17. The method of claim 10, wherein the conductive material comprises a metal, alloy, and/or doped semiconductor having a material selected from the group consisting of silver, copper, gold, iron, nickel, cobalt, platinum, palladium, titanium, aluminum, chromium, molybdenum, or a combination thereof.

18. The method of claim 11, wherein the nanoparticles comprise silver, copper, gold, iron, nickel, cobalt, platinum, palladium, titanium, aluminum, chromium, and/or molybdenum.
